(19) United States
(12) Patent Application Publication
(10) Pub. No.: US 2019/0312038 A1
(43) Pub. Date: Oct. 10, 2019

(54) SEMICONDUCTOR DEVICE INCLUDING FDSOI TRANSISTORS WITH COMPACT GROUND CONNECTION VIA BACK GATE

(71) Applicant: GLOBALFOUNDRIES Inc., Grand Cayman (KY)

(72) Inventors: Nigel Chan, Dresden (DE); Elliot John Smith, Dresden (DE); Ming-Cheng Chang, Dresden (DE)

(21) Appl. No.: 15/948,016

(22) Filed: Apr. 9, 2018

(51) Int. Cl. H01L 27/11; G11C 11/412; H01L 21/84; H01L 27/12; H01L 27/092

(52) U.S. Cl. CPC H01L 27/1104; G11C 11/412; H01L 27/092; H01L 27/1203; H01L 21/84

(57) ABSTRACT

The present disclosure provides manufacturing techniques and semiconductor devices in which a contact element at the source side of a pull-down transistor in a RAM cell may connect to the back gate region in a fully depleted SOI transistor architecture. In this manner, the complexity of at least some metallization layers may be reduced, thereby providing the potential of reducing parasitic bit line capacitance. Furthermore, in some illustrative embodiments, the contact regime for connecting the back gate region to a reference potential may be omitted, thereby reducing overall floor space of respective designs.

### BACKGROUND

### 1. Field of the Disclosure

The subject matter disclosed herein generally relates to semiconductor devices and manufacturing techniques in which sophisticated transistor elements based on fully depleted channel regions in combination with a back gate mechanism may be used, for instance, in dense device areas, such as static RAM (random access memory) areas.

### 2. Description of the Related Art

In the field of semiconductor devices, enormous progress has been made over the past decades by continuously reducing the critical dimensions of circuit elements, such as transistors, resistors, capacitors and the like. In particular, silicon-based CMOS techniques have made a major contribution to the development of extremely complex, yet cost-efficient, integrated circuits. For example, in modern integrated circuits, there is an ongoing trend to incorporate more and more functions into a single chip, thereby even forming entire systems on a single chip. To this end, packing density has to be increased by placing more and more individual circuit elements on a single substrate material, thereby requiring reduced lateral dimensions of these circuit elements, in particular, when device areas are considered in which a large number of transistor elements has to be provided in respective functional circuit portions.

One such device area of extremely dense packing density is a RAM circuit portion in which bits of information may have to be stored and read out with high speed, thereby typically implementing a so-called “static memory configuration,” in which a certain number of transistors may be combined to a logic component for storing a bit of information. In this case, access of the bit of information is determined by the switching speeds of the transistor elements involved, in combination with parasitic capacitances associated with supply voltage lines, word lines and essentially bit lines. That is, by providing a static cell configuration, which, in most cases, may be implemented on the basis of six transistor elements, high Write and Read speeds may be accomplished at the expense of having to provide a plurality of transistor elements per memory cell. That is, typically, in a six-transistor cell configuration, a pair of complementary transistors connected as an inverter is cross-coupled with another inverter, thereby forming a storage element, while Write and Read functionality may be accomplished by connecting these cross-coupled inverters, each requiring a pull-up transistor and a pull-down transistor, with respective pass gate transistors to respective lines, also referred to as bit lines, carrying bits of inverse logic state.

Consequently, by introducing new techniques resulting in significant reduction of lateral dimensions of transistor elements, the foot print of a corresponding RAM cell may also be reduced accordingly. On the other hand, since a large number of RAM cells may be typically required in more or less complicated circuit designs, any reduction of floor space of the individual RAM cells may translate into a significant increase of packing density and, thus, performance improvement and manufacturing cost reduction. Consequently, great efforts are being made in order to increase packing density of sophisticated transistor elements, in particular, in densely packed static RAM areas.

Since reduced lateral dimensions of transistor elements may not only contribute to increased packing density, but may also play an important role for generally enhancing transistor performance, many process techniques have been developed in recent years so as to continue reducing lateral dimensions, while attempting to address technical challenges that may be typically associated with the continuous reduction of critical dimensions. For example, in currently available sophisticated semiconductor devices, the CMOS technique may play a dominant role, even if mixed signal circuit portions, RF (radio frequency) circuit portions and the like may have to be incorporated into a single semiconductor substrate. In the CMOS technique, complementary transistors are provided in the form of field effect transistors, which typically include a channel region, a source region and a drain region, wherein current flow from the source region to the drain region is controlled by establishing an appropriate electric field across the channel region. Upon further reducing channel length, and, thus, increasing switching speed, appropriate control of the channel region has proven to be a challenging task, requiring significant efforts so as to enable further scalability of the channel length of sophisticated transistor elements. For example, complex gate electrode structures, i.e., electrode structures designed for achieving superior control of the channel region, may be implemented on the basis of specific material systems in order to accomplish sufficient capacitive coupling between the gate electrode structure and the channel region. Furthermore, it has been recognized that SOI (semiconductor- or silicon-on-insulator) architecture, in which a buried insulating layer may be formed below the channel region and the drain and source regions, may also contribute to superior transistor performance, since parasitic capacitance of the transistor body may be generally reduced compared to a bulk architecture, in which portions of the transistor body may extend into the depth of the substrate material. In recent developments, the further reduction of the channel length of sophisticated field effect transistors may, nevertheless, result in severe technical problems in controlling the channel region, which has triggered the development of so-called “three-dimensional transistor elements,” in which thin fins of semiconductor material having two or three surface areas may be enclosed by a gate electrode structure, thereby providing a folded or three-dimensional configuration of the near-surface areas for establishing a respective current flow. It turns out, however, that, although superior gate controllability may be achieved at an increased effective transistor width due to the folded nature of the current-carrying surface areas at reduced overall lateral dimensions, significant efforts may, nevertheless, have to be made in order to obtain the required three-dimensional configuration.

In other highly promising developments, the well-established planar transistor architecture may be preserved even at reduced channel length of 30 nm and even less, by providing a so-called “fully depleted” transistor configuration in which at least a significant portion of the channel region has a fully depleted configuration, i.e., a substantially charge carrier-free state for given control conditions, wherein a reduced amount of doping may also be applied, thereby avoiding doping-related variations in the channel region. A fully depleted configuration may be achieved by using a very thin semiconductor base material, for instance, 15 nm and even significantly less, which may also be used as a base material in other circuit portions, thereby, however, also resulting in certain technological challenges associated with the very thin semiconductor material. Moreover, in combination with SOI architecture, the respective fully depleted transistor configuration has proven to be a viable candidate for obtaining superior performance of transistor elements based on the well-established planar transistor architecture, thereby circumventing the technical challenges associated with sophisticated three-dimensional transistor architecture. The channel controllability in fully depleted transistor elements based on SOI architecture may be even further enhanced by using the buried insulating layer and the semiconductor material positioned therebelow as a “second” control electrode, also referred to as a “back gate.” That is, by applying an appropriate potential to the semiconductor region below the buried insulating layer, certain transistor characteristics, such as threshold voltage and the like, may be appropriately influenced so as to arrive in toto at superior transistor performance. On the other hand, certain disadvantages associated with the provision of very thin semiconductor material may be efficiently addressed by, for instance, providing a raised drain and source architecture in which a highly in situ doped semiconductor material may be grown on the very thin initial semiconductor material by epitaxial growth techniques in order to achieve sufficient process margin for forming a highly conductive metal semiconductor compound, such as a metal silicide, in these areas, on which respective contact elements may land upon forming a respective contact structure.

Since the concept of using fully depleted SOI transistor elements in sophisticated semiconductor devices has proven to be extremely effective in terms of manufacturing costs compared to applying three-dimensional transistor architectures, the planar transistor concept may also be efficiently applied to densely packed device areas, such as RAM cells, wherein the pull-up and pull-down transistor elements, as well as the pass gate transistor elements, may be formed on specifically dimensioned active regions so as to comply with the different current-carrying capacities of these transistors, while the back gate concept may also be applied. For example, in sophisticated RAM cells, a common doped semiconductor material may be provided below the buried insulating layer for a plurality of RAM cells forming a functional unity, for instance, representing 516 information bits, wherein the common doped semiconductor region may require a respective connection to a reference potential, such as ground potential. By providing a shared doped semiconductor region below the buried insulating layer, a respective single connection to the buried doped semiconductor material may suffice for the plurality of RAM cells in the functional unit, however, still requiring certain floor space for the connection mechanism in at least one of the RAM cells. Furthermore, each RAM cell may require electrical connections to the complementary pair of bit lines, the word line and supply voltage and ground potential, thereby also contributing to the total floor space required and to the complexity of the wiring system including the contact level and the metallization system of the device.

Although the sophisticated fully depleted SOI transistor configuration may basically provide superior transistor performance and, thus, switching speed for a given minimum floor space of respective active regions of the transistors in one RAM cell, the required number of electrical connections in the contact level and the metallization system may have to be adapted to the required connectivity of the RAM cell, thereby also demanding sophisticated manufacturing techniques and contributing to parasitic capacitance, which may limit the finally obtained performance of a respective RAM cell.

In view of the situation described above, the present disclosure relates to semiconductor devices and manufacturing techniques in which connectivity requirements of sophisticated fully depleted SOI transistors, in particular, in densely packed device areas, such as RAM areas, may be addressed, while avoiding or at least reducing the effects of one or more of the problems identified above.

### SUMMARY OF THE DISCLOSURE

The following presents a simplified summary of the disclosure in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is based on the concept that, for a given basic layout of fully depleted SOI transistor elements, the connectivity requirements thereof may be addressed more efficiently by taking advantage of the presence of a doped semiconductor region positioned below the buried insulating layer by connecting the source region of a respective transistor element directly with the source region of the transistor element under consideration, if these two regions may have to be operated on the basis of the same reference potential. For example, in RAM areas, the pull-down transistor, i.e., one of the transistor elements of the complementary transistor pair of an inverter of the RAM cell, has to typically “pull down” the respective signal node to ground potential or VDD, while, at the same time, the doped region, i.e., the “back gate” region, may also be typically held at ground potential or VDD. Consequently, in some illustrative embodiments disclosed herein, the required potential may be supplied via the back gate mechanism and a direct connection between the source region and the back gate region, thereby providing the potential of significantly reducing overall complexity and, in particular, parasitic capacitance of one or more following levels of the metallization system, since a “direct” connection of the source region of the transistor element under consideration to the metallization system may be omitted, at least for some transistor elements. This concept may also be advantageously applied to RAM cells, since, in particular, reduced complexity in one or more of the overlying metallization layers may contribute to the reduced parasitic capacitance of the respective bit lines, thereby enhancing performance with respect to Read and Write operations. Moreover, since a single commonly connected doped semiconductor region or back gate region may be typically provided for a plurality of RAM cells, the reduction of connection complexity in the metallization layer may be accomplished for a plurality of RAM cells without contributing to further process complexity. In other illustrative embodiments disclosed herein, the direct connection between a source region and a back gate region may be used for connecting the back gate region to the required reference potential, thereby eliminating the need for a specific dedicated connection region in one of the RAM cells.

According to one illustrative embodiment disclosed herein, a semiconductor device is provided. The semiconductor device includes an active region of a transistor element, which includes a channel region, a gate electrode structure formed above the channel region, a drain region and a source region. The semiconductor device further includes an isolation structure laterally bordering the active region. Moreover, a buried insulating layer is formed below the active region. The semiconductor device further includes a doped semiconductor region formed below the buried insulating layer and electrically connected to a reference potential. Additionally, the semiconductor device includes a contact element formed in a dielectric material that encloses the transistor element, wherein the contact element connects to the source region and extends to the doped semiconductor region so as to establish electrical connection to the reference potential.

A further illustrative embodiment disclosed herein relates to a semiconductor device. The semiconductor device includes a doped semiconductor region formed below a buried insulating layer, wherein the doped semiconductor region is connected to a reference potential. The semiconductor device further includes a plurality of RAM cells formed above the buried insulating layer and the doped semiconductor region. Additionally, the semiconductor device includes pull-down transistor elements provided in each of the plurality of RAM cells, wherein at least one of the pull-down transistor elements comprises a source region that is connected to the doped semiconductor region by a contact element that extends to the doped semiconductor region.

According to yet another illustrative embodiment disclosed herein, a method is provided. The method includes selecting at least one of lateral position and lateral shape of a contact element for a source region of a transistor element so as to provide for lateral overlap of the contact element and an isolation region adjacent to the source region. Moreover, the method includes forming the contact element on the basis of the lateral overlap so as to extend through a buried insulating layer and to a doped semiconductor region formed below the buried insulating layer that is connectable to a reference potential.

### BRIEF DESCRIPTION OF THE DRAWINGS

The disclosure may be understood by reference to the following description taken in conjunction with the accompanying drawings, in which like reference numerals identify like elements, and in which:

FIG. 1A schematically illustrates a top view of a semiconductor or a layout thereof demonstrating a static RAM cell, including a plurality of transistor elements, wherein each of the RAM cells may include an individual connection via the metallization system to the ground potential for each pull-down transistor according to illustrative embodiments;

FIG. 1B schematically illustrates a cross-sectional view of the semiconductor device along the line D3 of FIG. 1A;

FIG. 2A schematically illustrates a top view of the semiconductor device or layout thereof in accordance with illustrative embodiments, thereby illustrating at least one RAM cell having a modified contact level so as to directly connect the source region of a pull-down transistor with a back gate region, according to illustrative embodiments;

FIG. 2B schematically illustrates a cross-sectional view of the semiconductor device along the line IIB of FIG. 2A, according to Illustrative embodiments;

FIG. 2C schematically illustrates a cross-sectional view of a portion of a semiconductor device during a manufacturing stage in which a contact element is to be formed so as to directly connect the source region of a transistor element with a doped semiconductor region or back gate region of one or more transistor elements, according to illustrative embodiments;

FIGS. 3A, 4A, 5A and 6A schematically illustrate top views of semiconductor devices or layouts thereof in which a modified contact level and respective overlying metallization levels are illustrated, wherein each pull-down transistor of a plurality of static RAM cells includes a direct connection between source region and back gate region, according to illustrative embodiments, while FIGS. 3B, 4B, 5B and 6B schematically illustrate respective top views in which a non-modified contact level may be provided, wherein such a conventional concept may be completely replaced or at least partially replaced by the modified concepts illustrated in FIGS. 3A, 4A, 5A and 6A, according to illustrative embodiments; and

FIG. 7 schematically illustrates a cross-sectional view of a semiconductor device according to illustrative embodiments, wherein a contact regime for connecting a reference potential to the back gate region of a plurality of RAM cells is illustrated, while this figure also indicates the potential of reducing the overall foot print of a RAM design by omitting the respective contact regime in other illustrative embodiments, when the back gate region may be connected to the reference potential by at least one of the source region of respective pull-down transistors.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The following embodiments are described in sufficient detail to enable those skilled in the art to make use of the invention. It is to be understood that other embodiments would be evident, based on the present disclosure, and that system, structure, process or mechanical changes may be made without departing from the scope of the present disclosure. In the following description, numeral-specific details are given to provide a thorough understanding of the disclosure. However, it would be apparent that the embodiments of the disclosure may be practiced without the specific details. In order to avoid obscuring the present disclosure, some well-known circuits, system configurations, structure configurations and process steps are not disclosed in detail.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

The present disclosure generally provides a concept in which the floor space of individual transistors and, thus, of transistor elements provided in a densely packed device region, may be reduced, and/or the complexity of a metallization system provided above the contact level may be reduced by implementing a contact element at the source region of an FDSOI (fully depleted SOI) transistor element such that a direct connection to the back gate region of the transistor element may be established on the basis of the contact element, when the back gate region and the source region have to be operated on the basis of the same reference potential, such as ground potential.

In this context, it should be understood that a “direct” connection between a first region and a second region, such as a source region and a doped semiconductor region or back gate region, when established by an intermediate component, such as a contact element, is to be considered such that the intermediate component, such as the contact element, is in contact with both the first region and the second region, such as the source region and the back gate region.

In the context of semiconductor regions, a direct connection of semiconductor regions, such as the doped semiconductor region formed below a buried insulating layer, also referred to herein as back gate region, is to be understood such that at least a portion of the semiconductor region in one area, for instance, in the area below one transistor element, extends into the area of the respective semiconductor material of another transistor element, thereby establishing a “direct” connection of different portions of a back gate material of two or more transistor elements.

According to the principles disclosed herein, it has been recognized that, in many cases, the additional control mechanism provided by the back gate mechanism may not require different control voltages at the back gate material and the source of a specific transistor element, wherein any such configuration may, according to the principles disclosed herein, be taken advantage of by “directly” connecting the source region and the back gate region by a contact element. Since, in some cases, the back gate region may have already implemented an appropriate contact regime for connecting to the desired reference potential, the current supply of the source region of the transistor element under consideration may, thus, be efficiently accomplished via the contact regime of the respective back gate mechanism, in particular, in situations when the required current flow is moderately low. For example, in many sophisticated, yet well-established, RAM configurations, the back gate region of a plurality of RAM cells may be internally or directly connected and may be finally connected to a single contact mechanism. In many such cases, a total current flow, for instance, even if all of the respective transistors having their source regions connected to the back gate region may concurrently draw current, may not exceed a specific limit. In this case, the back gate mechanism may reliably feed the required current to the respective transistor elements. For example, when considering a plurality of RAM cells, such as 256 RAM cells representing 256 information bits, a Read operation may require a current flow on the respective bit line connected to these RAM cells, which may be typically in the range of 20 μA. Consequently in this case, a total current of approximately 5 mA would have to be supplied via the back gate mechanism, which is well within the capabilities of such a configuration.

In other illustrative embodiments disclosed herein, the current supply may still be accomplished via the metallization system, for instance, by providing for some of the pull-down transistors of a RAM cell, a direct connection to the metallization system, while, on the other hand, the back gate region may be connected by any direct source to back gate connections. In this case, the respective back gate connection regime may be omitted, which may be frequently provided at an edge cell, thereby enabling reduced overall space consumption in complex RAM designs.

By providing a contact element directly connecting the source region and the back gate region of at least some of a plurality of transistor elements, the manufacturing challenges in one or more of the above-lying metallization layers may be significantly relaxed due to the potential of enabling the omission of at least some of the metal components in one or more of these metallization layers. Therefore, in particular, in RAM areas of the semiconductor device, it may suffice to implement a reduced number of metal components in one or more metallization layers, which may not only contribute to reduced process complexity, but also to enhanced performance as, for instance, parasitic capacitance of bit lines may be reduced.

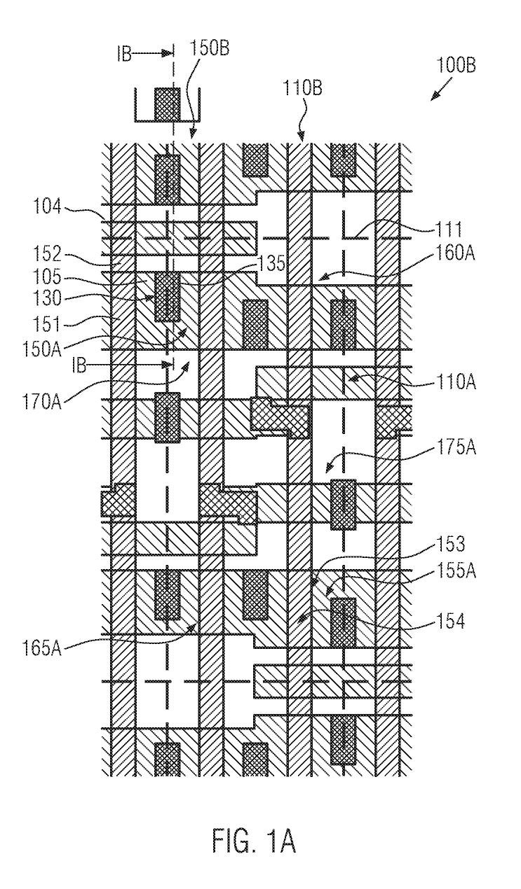

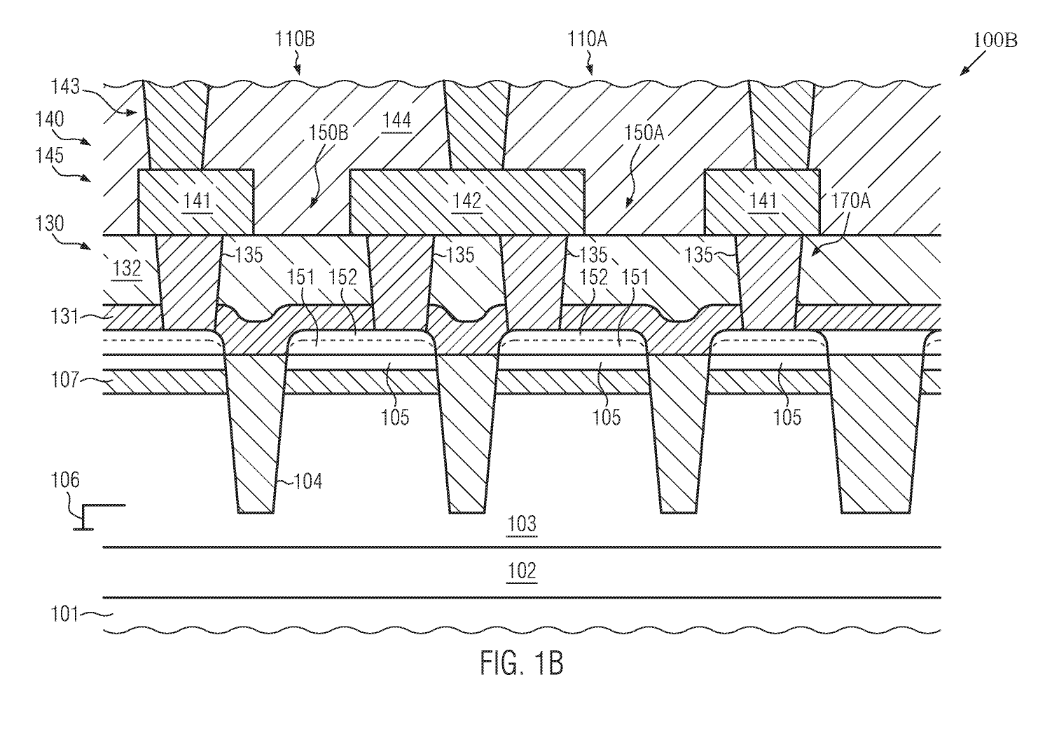

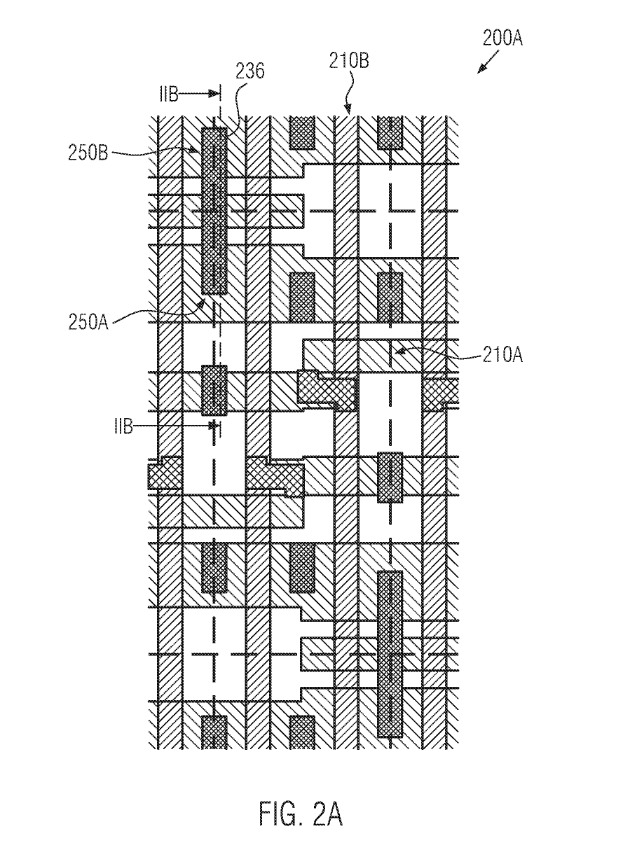

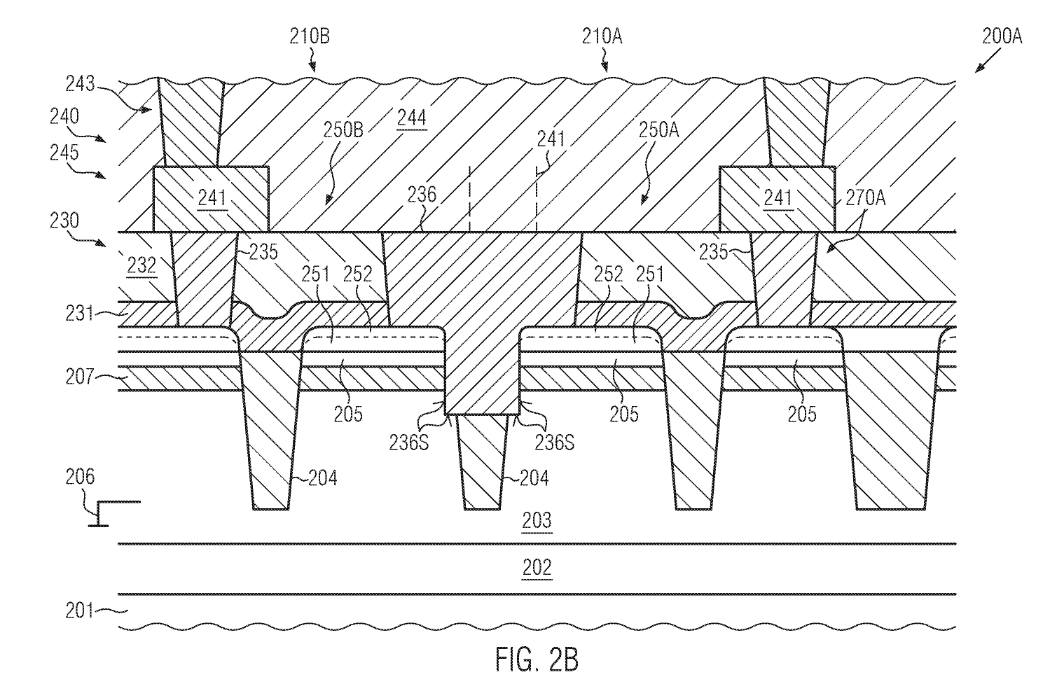

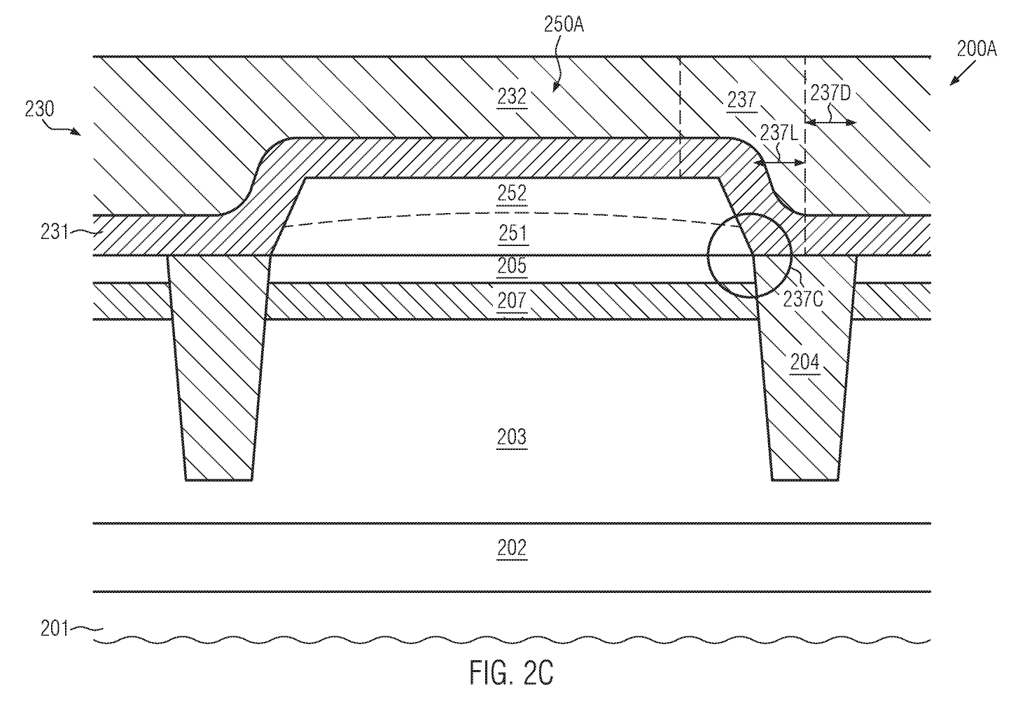

In the following, semiconductor devices formed in accordance with strategies considered as having certain limitations are shown in and explained with reference to FIGS. 1A, 1B, 3B, 4B, 5B and 6B. On the other hand, semiconductor devices including modified connectivity as discussed above and as will be discussed below are shown in and explained with reference to FIGS. 2A, 2B, 2C, 3A, 4A, 5A, 6A and 7, wherein generally it may also be referred to the devices of FIGS. 1A, 1B, 3B, 4B, 5B and 6B when appropriate.

FIG. 1A schematically illustrates a top view of a semiconductor device 100B or its layout in a certain manufacturing stage. As illustrated, the semiconductor device 100B may include a plurality of transistor elements formed in accordance with the FDSOI architecture, i.e., the transistor elements may include a fully depleted area in respective channel regions and the channel region and respective source and drain regions may be bordered in the vertical direction, i.e., in FIG. 1A, the direction pointing into the drawing plane of FIG. 1A, by a buried insulating layer, followed by a doped semiconductor region or back gate region, as will be explained in more detail later on.

In some illustrative examples as, for instance, illustrated in FIG. 1A, the respective transistor elements may be grouped into logic entities, such as RAM cells, typically comprising six transistors for a single cell. For example, as illustrated, a first RAM cell 110A may be provided, surrounded by respective neighboring RAM cells, wherein, for convenience, only one is indicated by 110B, and wherein only a portion of the surrounding RAM cells is illustrated. The functional boundaries of the RAM cell 110A are illustrated by the line 111, which is to be understood as a non-functional design line or border. As illustrated, the RAM cell 110A may include a first pull-down transistor 150A and a second pull-down transistor 155A formed on the basis of an appropriately dimensioned active region 105, including source and drain areas, as well as a channel region 153, which, in turn, is covered by a respective gate electrode structure 154. As previously indicated, at least a portion of the channel region 153 may be designed so as to exhibit a fully depleted configuration, as discussed above.

Moreover, the RAM cell 110A may include pass gate transistors 160A, 165A, which may have a configuration similar to the pull-down transistors 150A, 155A, which, in the design shown, may have a slightly different transistor width, since the respective active region 105 may have reduced dimensions in the width direction, i.e., in FIG. 1A, the vertical direction. The various active regions are separated by isolation regions 104, such as trench isolation regions. It is to be noted that respective gate electrode structures and active regions will also be denoted by 153 and 105, irrespective of any differences with respect to lateral size and shape, material composition, doping and the like.

Moreover, the RAM cell 110A may include pull-up transistors 170A, 175A, which may typically represent transistor elements of complementary type with respect to the pull-down transistors 150A, 155A, and which may typically have a reduced current-carrying capacity, so that a respective transistor width may be significantly less compared to the width of respective pull-down transistors and also of pass gate transistors, such as the transistors 150A, 155A, 160A, 165A.

It should be understood that the semiconductor device 100B may be provided in a relatively advanced manufacturing stage in which a contact level 130, including a plurality of contact elements 135, may be formed. It should be noted that the contact elements 135 in the contact level 130 may be denoted by the same reference signs, irrespective of the spatial position and size and shape of corresponding contact elements, and irrespective of the specific transistor elements to which these contact elements may connect. Further details regarding the configuration of the semiconductor device 100B and the contact level 130 will be discussed later on in more detail with reference to FIG. 1B.

FIG. 1B schematically illustrates a cross-sectional view of the semiconductor device 100B taken along the line IB of FIG. 1A. As illustrated, the semiconductor device 100B may include a substrate 101, which may be provided in the form of any appropriate carrier material, such as a crystalline semiconductor material in the form of silicon, silicon/germanium, silicon/carbon and the like, or any other appropriate carrier material. Furthermore, at least portions of the semiconductor device 100B may include doped semiconductor materials within the substrate material 101 in order to provide superior functionality with respect to a back gate mechanism and the like. For example, a relatively deep-lying doped region 102 may be provided having an appropriate type of doping, such as an N-type doping, when the substrate 101 may represent a P-doped substrate material, so that the doped region 102 may efficiently electrically insulate upper portions of the semiconductor device 100B from the substrate material 101, when having P-type conductivity. Moreover, a doped semiconductor region 103 may be formed above the doped region 102 and may have a required type of dopant profile in order to establish a back gate mechanism, as discussed above. For example, the doped semiconductor region 103, also referred to as back gate region 103, may represent a P-doped region and may be electrically connected to a reference potential 106, which, in some examples, may represent ground potential. In some examples as, for instance, illustrated in FIG. 1B, the doped semiconductor region 103 or back gate region may represent a region that is directly connected in between a plurality of transistor elements, so that at least a portion of this region extends from one transistor area to another. Therefore, as discussed above, in some illustrative embodiments, the back gate region 103 may be provided as an interconnected semiconductor material for a plurality of transistor elements forming a functional unit, such as a plurality of RAM cells, such as the cells 110A, 110B.

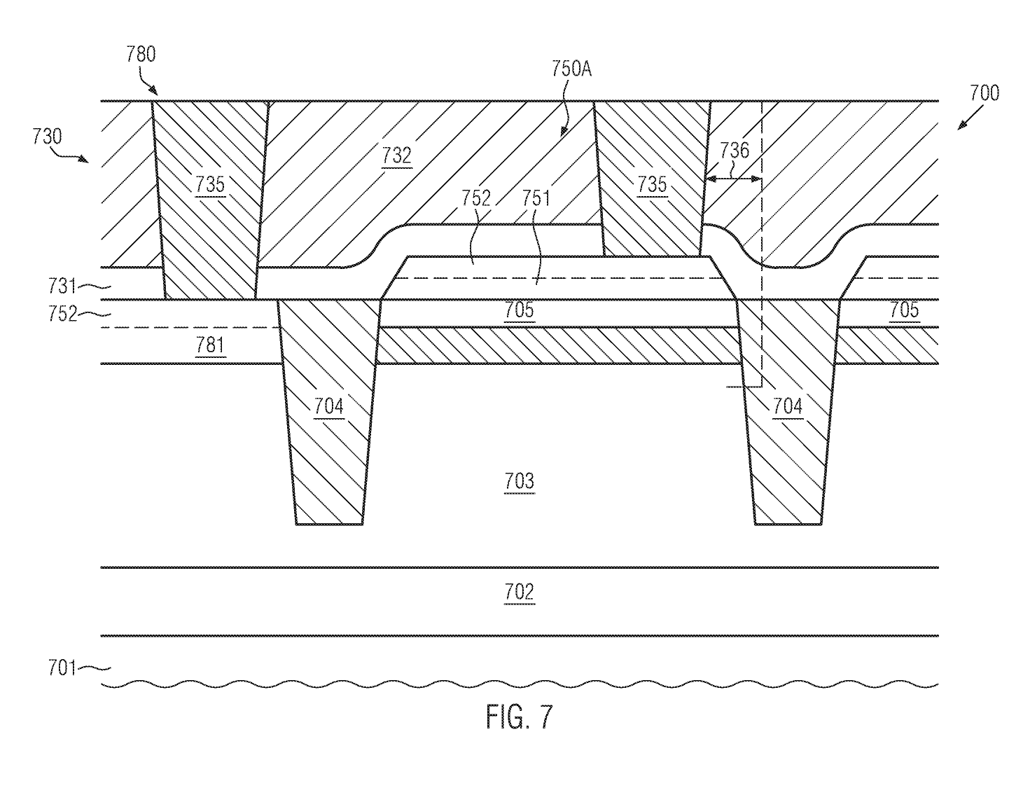

The connection to the reference potential 106 may be established, in some illustrative embodiments, on the basis of a connection regime or mechanism, as will be explained later on in more detail with reference to FIG. 7, and, in other embodiments, in addition to or alternatively, by direct connection to a source region of one or more of the transistor elements in one or more of the cells 110A, 110B, as will be discussed later on in more detail.

Moreover, the semiconductor device 100B may include a buried insulating layer 107, which may be formed of any appropriate material(s) or material composition, such as silicon dioxide, silicon nitride, silicon oxynitride, high-k dielectric materials and the like. Moreover, a thickness of the buried insulating layer 107 may be typically selected so as to comply with specific requirements for providing superior transistor control when, for instance, in certain device areas, any other reference potential 106 may be applied in a static or dynamic manner to a respective portion of the respective back gate material 103. For example, the thickness of the buried insulating layer 107 may range from approximately 5-50 nm.

The active regions 105 of the various transistors, such as the transistors 150B, 150A, 170A, may be formed above respective portions of the buried insulating layer 107 and may have any appropriate lateral size and shape, as defined by the isolation regions 104 and as discussed above in the context of FIG. 1A, while also material composition, doping and the like are appropriately selected in view of the characteristics of the respective transistor element. For example, the active region 105 of the transistor 170A may be formed on the basis of a different doping and/or material composition when representing a P-type transistor, while the pull-down transistors 150A, 150B may represent N-type transistors. As previously discussed, the active regions 105 may be generally formed on the basis of an initial semiconductor material having a sufficiently reduced thickness in order to establish, at least in central portions of the respective channel regions 153, a fully depleted configuration.

Moreover, the transistor elements 150B, 150A, 170A may include the respective gate electrode structures 154 (see FIG. 1A) having any appropriate configurations of dielectric material, electrode material or materials, gate length and the like. It should be noted that, in sophisticated applications, a gate length of 30 nm and even less may be implemented, while respective width dimensions of the transistor 150A, i.e., in FIG. 1B the horizontal extension of the respective active regions 105, may be in the range of 70 nm and even less, while a respective width dimension of pull-up transistors, such as the transistor 170A, may be approximately 50 nm and even less. It is to be noted that, in other embodiments, the lateral dimensions of the transistor elements are specifically restricted to specific values and depend on the basic device design.

As already discussed above, respective drain and source regions, for instance, the source regions 151, of any of the transistor elements of the RAM cells 110A, 110B may be implemented in the form of a raised drain and source architecture, since a desired reduced contact resistivity may be difficult to achieve on the basis of the thin active regions 105. To this end, an epitaxially grown and in situ doped semiconductor material may be formed at an appropriate manufacturing stage, thereby providing the source regions 151 with a raised configuration. In this manner, integrity of the thin active region 105 in the drain and source areas may be preserved, while still providing reduced contact resistivity upon forming metal-containing materials 152, for instance, in the form of a metal semiconductor compound, such as a metal silicide, in at least a portion of the raised drain and source regions 151.

Moreover, the contact level 130 may include any appropriate dielectric materials, such as materials 131 and 132, for instance, in the form of silicon nitride, hydrogen enriched silicon dioxide and the like, as is required by device and design criteria. The contact elements 135 may, thus, connect to the respective drain and source regions, for instance, the source regions 151 and, in particular, to the low resistance areas 152. The contact elements 135 may include any appropriate material or material composition, such as tungsten, in combination with an appropriate barrier layer and the like. Moreover, in the manufacturing stage shown in FIG. 1B, a portion of a metallization system 140 may be provided, for instance, a first metallization layer 145, including any appropriate dielectric material or materials 144, metal lines or components 141, 142 in combination with additional components 143 that provide direct connection to a further metallization level or layer that is not shown in FIG. 1B.

As is evident from FIG. 1B, the contact elements 135 connecting to the respective source regions 151 of the pull-down transistors 150B and 150A of the neighboring RAM cells 110B, 110A are connected to a required potential by means of the metal components 141, 142 of the relevant portion of the metallization system 140. For example, as discussed above, the source regions 151 may require the reference potential 106 and may, thus, be connected via the metallization system 140 to the respective ground supply line (not shown). Furthermore, as is evident from FIG. 1B, depending on the width dimensions of the respective transistor elements in the RAM cells 110A, 110B, the metal components 141, 142 in the metallization system 140 may also have to be adapted in size and position so as to comply with the connectivity requirements of the RAM cells 110A, 110B, thereby increasingly contributing to overall complexity in forming the metallization system 140 and also increasing parasitic capacitance due to reduced lateral distances between neighboring metal components, such as the components 141 and 142.

A typical process flow for forming the semiconductor device 100B as shown in FIGS. 1A and 1B may include the following processes. The substrate 101 may be prepared or obtained from a specific manufacturer in the form of an SOI substrate, including the substrate material 101 and the buried insulating layer 107, followed by an initial semiconductor layer for forming the active regions 105. For example, the initial semiconductor layer may be provided with a thickness of 15 nm and even less with low thickness variations, from which respective active regions may be formed, for instance, by removal processes, epitaxial growth techniques and the like. To this end, any well-established process strategies may be applied.

At any appropriate manufacturing stage, the isolation regions 104 may be formed prior to or after incorporating appropriate dopant species so as to establish the doped region 102 and the doped semiconductor region 103, also referred to as back gate region 103. To this end, well-established implantation techniques may be applied, in combination with appropriate masking regimes. The isolation regions 104 may be formed upon laterally bordering the respective regions 105 on the basis of sophisticated lithography, deposition, etch and planarization techniques. Thereafter, appropriate materials may be deposited and patterned in order to form the gate electrode structures 154, thereby also establishing a desired gate length. As previously discussed, based upon the initial thin semiconductor material, the respective channel regions 153 (see FIG. 1A) may be obtained so as to achieve the required fully depleted configuration in at least a central portion thereof. Thereafter, the semiconductor material for the raised drain and source regions, such as the source regions 151, may be deposited on the basis of selective epitaxial growth techniques, while also incorporating desired dopant species, if considered appropriate.

Next, the metal-containing material 152 may be formed, for instance, by applying well-established silicidation techniques and the like. Thereafter, the one or more dielectric materials, such as the materials 131 and 132, may be deposited by applying well-established deposition techniques, followed by a planarization in order to provide a planar surface topography for forming the contact elements 135. To this end, appropriate lithography techniques may be applied, wherein the lateral size, shape and position may be defined by using well-established techniques, for instance, providing hard mask materials and the like, in order to appropriately form respective openings which may then be filled with a barrier material, a highly conductive metal material and the like. Thereafter, planarization techniques may be applied to remove non-required material residues. The respective patterning process for forming openings for the contact elements 135 may include appropriate selective etch techniques, for instance, for etching through the material 132 while using the material 131 as an etch stop material, followed by a further etch sequence etching through the layer 131 and finally landing on the highly conductive materials 152, which may act as a stop material. Due to the appropriate positioning and dimensioning of the openings for the contact elements 135, the etch process for etching through the layer 131 may be reliably stopped within the material 152 without unduly removing material of the isolation structures 104. Any such exposure of the material 104 may otherwise result in significant material removal in the isolation structure 104 and the relevant portion of the buried insulating layer 107.

After completing the contact level 130, the metallization system 140 may be formed by depositing any appropriate dielectric material or materials, such as the one or more materials 144, and patterning the same based on sophisticated lithography techniques in order to form the metal components 141, 142. Thereafter, a further metallization layer may be provided, for instance, in the form of the contacts or vias 143, followed by respective metal lines (not shown).

Consequently, as also discussed above, at least within the metallization layer 145, a relatively complex structure may result due to the presence of the metal components 141, 142.

According to findings of the present disclosure, it has been recognized that at least some of the source regions 151 of the transistors 150B, 150A may be connected to the doped semiconductor region or back gate region 103 by providing appropriately positioned and dimensioned contact elements, thereby enabling the omission of at least some of the metal components 142.

Some illustrative embodiments of the present disclosure will now be described with reference to FIGS. 2A-2C, wherein elements and components similar to those described above are denoted by the same reference numerals except for the leading digit and with respect to a detailed description thereof it is also referred to the device 100B of FIGS. 1A and 1B.

FIG. 2A schematically illustrates a top view of the semiconductor device 200A according to some illustrative embodiments. As discussed above in the context of the device 100B, the semiconductor device 200A may include at least some transistor elements in which a source region may be connected to the doped semiconductor region 103 (see FIG. 1B) by an appropriately dimensioned and positioned contact element in order to provide the possibility of reducing overall complexity of the respective metallization system.

In FIG. 2A, it may be assumed that a RAM cell 210A and at least its neighboring cell 210B may have respective pull-down transistors 250A, 250B with a specifically adapted contact element 236 that may establish a direct connection between the respective source region and the doped semiconductor region, as discussed above. It should be appreciated that, in some illustrative embodiments, the RAM cells as illustrated in FIGS. 1A and 1B, i.e., the cells 110A, 110B of FIGS. 1A and 1B, may be replaced entirely by the cell design as shown by the cells 210A, 210B of FIG. 2A, while, in other illustrative embodiments, only a part of the respective “conventional” RAM cells of FIGS. 1A and 1B may be replaced by the cells 210A, 210B of FIG. 2A having the modified contact regime. In other illustrative embodiments, a part of the modified contact regime, as will be discussed later on in more detail with reference to FIG. 2B, may be implemented in any of the RAM cells as shown in FIGS. 1A and 1B, while, at the same time, only a part of the corresponding modified contact elements 236 may be provided in combination with a contact regime in the metallization system 140 of FIG. 1B, while other modified contact elements 236 may be provided with a contact regime as will be discussed in the following with reference to FIG. 2B.

FIG. 2B schematically illustrates a cross-sectional view of the semiconductor device 200A along the line IIB of FIG. 2A. As illustrated, the RAM cells 210A, 210B may have substantially the same configuration as previously discussed in the context of FIGS. 1A and 1B in terms of the respective transistor elements, except for the configuration at the source side of at least one of the transistors 250A, 250B. That is, the respective contact element 236 may be provided with appropriate lateral size and dimension, as well as lateral position, so as to connect to a respective source region 251 and also directly connect to the doped semiconductor region 203. To this end, at least a portion of the contact element 236 may extend through a buried insulating layer 207 and may extend into a respective isolation region 204, while a lateral size of the respective portion of the contact element 236 may be selected so as to provide at least some surface areas 236S which may be in direct contact with the doped semiconductor region 203. Consequently, the modified element 236 may provide a “short circuit” between the respective source region 251 and the doped semiconductor or back gate region 203 by means of the contact surface areas 236S. In the embodiment shown, the contact element 236 may be sized so as to also span the isolation region 204 between the source regions of the neighboring transistors 250B, 250A, thereby providing superior process margin when forming the modified contact element 236. In other illustrative embodiments (not shown), the contact element 236 may be provided separately for the transistors 250A, 250B or may be implemented for one of these transistors only, if the other transistor may be provided in line with the conventional concept in which individual contact elements may be used. That is, in some embodiments (not shown), at least one contact element 236 may extend down to the doped semiconductor region 203, while another one may or may not extend to the semiconductor region 203. Thus, in some illustrative embodiments (not shown), one portion of the contact element 236 may be provided in the form as illustrated in FIG. 1B for the elements 135, while another portion of the contact element 236 may be formed so as to extend down to the region 203 having respective contact surfaces 236S, as shown in FIG. 2B.

Moreover, in the metallization layer 245 of the system 240, a significantly reduced degree of complexity may be achieved, since the number and/or the size of certain components in the metallization layer 245 may be reduced. For example, in one illustrative embodiment, a respective metal component, such as the component 142 (see FIG. 1B), may be completely omitted so that the contact element 236 may have no direct connection to the metallization system 240. In other illustrative embodiments, as indicated by the dashed lines, a metal component 241, similar to the components 141, may be provided, thereby still substantially increasing overall distance between neighboring metal components 241, which may also contribute to reduced complexity and enhanced performance. In this case, the optional component 241 connecting to the modified contact element 236 may still provide low resistivity and high current-carrying capacity for the respective source regions 251. Consequently, in some illustrative embodiments, at least some of the modified contact elements 236 may be connected to the metallization system 240, for instance, on the basis of the component 241 having the reduced lateral size compared to the design, as shown in the context of the component 142 in FIG. 1B, thereby reducing overall complexity.

In still other illustrative embodiments (not shown), a connection regime as shown in FIG. 1B may be provided for at least some of the RAM cells 210A, 210B, in combination with the modified contact regime based on the contact element 236 in other RAM cells, thereby, in toto, reducing overall complexity and enhancing performance in the metallization system 240, while still providing high current-carrying capacity.

The semiconductor device 200A as illustrated in FIG. 2B may be formed on the basis of substantially the same manufacturing strategy as discussed above in the context of FIGS. 1A and 1B. It should be appreciated, however, that the corresponding layout of the contact level 230 and of the metallization system 240 may have to be adapted in accordance with the number of modified contact elements 236, the number of metal components 242 to be omitted in the metallization layer 245, or the number of metal components receiving an adapted lateral size for respective modified contact elements 236, as discussed above. When forming, for instance, the contact level 230, the size, position and shape of a respective opening for the contact element 236 may result in significant exposure of the isolation region 204 upon performing at least the final etch process for etching through the dielectric layer 231. Consequently, during this etch process, the etch front will propagate into the buried insulating layer 207 and the isolation region 204 and may, thus, finally reach the doped semiconductor region 203, thereby forming the respective contact surface areas 236S as shown in FIG. 2B. Consequently, after filling the openings for the contact elements 235, 236 with appropriate barrier and metal-containing materials, the contact element 236 may provide a direct connection between respective source regions 251 and respective portions of the doped semiconductor region 203.

FIG. 2C schematically depicts the semiconductor device 200A according to further illustrative embodiments, illustrating a transistor element, such as the transistor element 250A, in which a single contact element may provide direct connection between the source region 251 and the doped semiconductor region 203. As shown, after establishing the contact level 230 by depositing the dielectric materials 231 and 232 and after planarizing these materials, a lithography process may be applied in which an appropriately selected lithography mask and/or respective overlay mechanisms may be applied in order to form a respective opening 237 extending through the dielectric materials 232 and 231.

In order to ensure sufficient propagation of the respective etch front when etching the openings of all of the contact elements, the opening 237 may be dimensioned and/or positioned such that a minimum lateral offset and, thus, overlap 237L with respect to the isolation region 204 may be achieved upon actually forming the opening 237. To this end, the lateral size and/or the position of the opening 237 may be selected so as to shift the outer edge of the opening 237 outwardly, as indicated by 237D, in order to obtain the required minimum overlap 237L. It has been recognized by the inventors that the minimum overlap 237L may be readily established on the basis of given etch recipes and design criteria so as to reliably etch through the buried insulating layer 207 and the isolation region 204 within a critical area 237C during the final etch process for etching through the dielectric layer 231. For example, for given etch parameters and etch times, the minimum overlap 237L may be several nanometers, for instance, approximately 6-10 nm, which may already suffice to reliably form the opening 237 so as to extend into the semiconductor region 203, while still preserving sufficient process margin for the formation of other contact elements, such as the contact elements 135, 235 (see FIGS. 1B, 2B) in which a respective “direct connection” between respective source regions and drain regions and the semiconductor region 203 has to be avoided. Consequently, after forming the opening 237 so as to extend through the critical area 237C, the subsequent filling with appropriate conductive materials may result in “shorting” the source region 251 and the doped semiconductor region 203, as also discussed above in the context of FIG. 2B. Thereafter, the further processing may be continued by forming the metallization system, such as the system 140, 240 (see FIGS. 1B, 2B), wherein, in some embodiments, a metal component may be provided for some of the contact elements to be formed on the basis of the opening 237 so as to directly connect to a respective contact element formed in the opening 237, while, in other illustrative embodiments, such a direct contact to the metallization system may be omitted for all of the respective contact elements, as previously discussed.

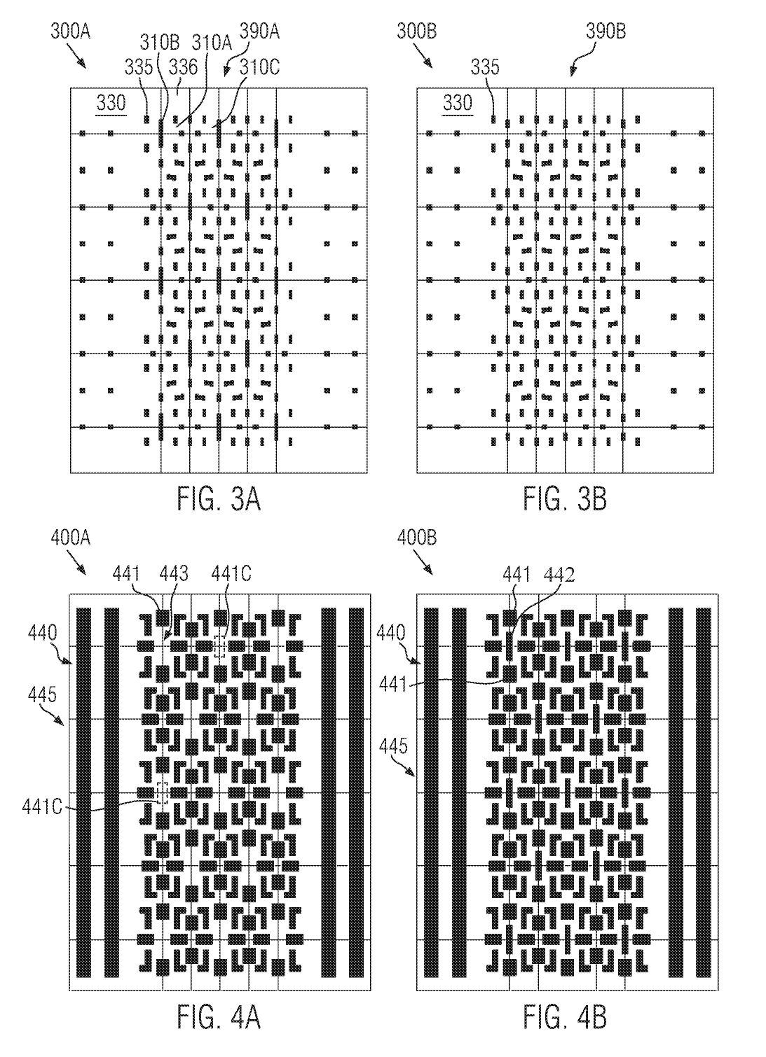

FIGS. 3A and 3B schematically illustrate top views of semiconductor devices or respective layouts 300A (FIG. 3A) and 300B (FIG. 3B), wherein the concept of a modified contact element may be implemented at least in some of respective transistor elements of the semiconductor device or layout 300A.

As shown in FIG. 3A, the semiconductor device 300A or its layout may include a contact level 330 including “standard” contact elements 335 and at least some modified contact elements 336, which may provide a respective direct contact between a respective source region and a doped semiconductor region or back gate region as, for instance, explained and described in the context of FIGS. 2A, 2B and 2C. For example, the semiconductor device 300A may include a plurality of RAM cells 310A, 310B, 310C, at least some of which may form a functional unit, for instance, 516 unit cells for storing 516 bits of information, wherein the respective functional unit may be supplied by a single Word line (not shown) for addressing the respective functional unit, indicated by 390A. In the embodiment shown in FIG. 3A, all of the respective pull-down transistors (not shown) may include the modified contact element 336, wherein, as shown, respective neighboring source regions of neighboring pull-down transistors may be bridged by the contact elements 336 as, for instance, explained in detail with reference to FIGS. 2Aand 2B.

FIG. 3B schematically illustrates the semiconductor device or a layout thereof 300B in which the contact level 330 may include exclusively “standard” contact elements 335, as previously discussed in the context of FIGS. 1A and 1B. Respective RAM cells may also form a functional unit 390B, similar to the device shown in FIG. 3A.

It should be appreciated that, in some illustrative embodiments (not shown), at least some of the “standard” RAM cells of the device 300B may replace one of the RAM cells 310A, 310C, 310B of the device 300A in order to provide superior current-carrying capacity for the respective currents to be conducted by the respective transistor elements, as also discussed above.

Furthermore, in some illustrative embodiments, some of the contact elements 236 of the device 300A may be provided in combination with metal components in the overlying metallization system, as also, for instance, discussed above in the context of FIG. 2B, thereby providing a direct connection between the respective contact element 336 and the metallization system and therefore ensuring a very low resistance connection to the reference potential, such as ground potential, as also discussed above. Consequently, a low ohmic connection to the doped semiconductor region or back gate region may also be accomplished by these contact elements 336 having a direct connection to the metallization system. Consequently, in some illustrative embodiments, the device 300A may include one or more of the conventional RAM cells having the conventional design as shown in FIG. 3B, while, in other cases, a mixture of bridging contact elements 336 with and without direct elements to an overlay metallization system may be provided, without the “standard” contact elements 335. It is to be noted that, even if a mixture of contact elements 336 and 335 and/or a mixture of contact elements 336 with and without direct connection to the metallization system are used, nevertheless, significant advantages in terms of performance and/or reduced complexity may be achieved.

FIGS. 4A and 4B schematically illustrate semiconductor devices or their respective layouts 400A (FIG. 4A) and 400B (FIG. 4B), respectively, with a further device level. That is, FIGS. 4A and 4B schematically illustrate a top view of a respective metallization system 440, such as a metallization layer 445, as previously discussed in the context of the metallization system 140, 240 and the layer 145, 245 in FIGS. 1A, 1B and 2A, 2B. Thus, in some illustrative embodiments, the layer 445 may include metal components 441 connecting to contact elements, which may connect to drain or source regions of transistors that may not require a direct connection between source region and back gate region, as discussed above. Consequently, the spacing between respective metal components 441 provided in the vertical direction in FIG. 4A may be increased due to a void 443 in which, in other strategies, a respective metal component would have to establish direct contact between the underlying contact elements and the metallization system 440.

FIG. 4B, on the other hand, illustrates the standard connection regime in the metallization system 440 and the layer 445, wherein a respective metal component 442 connecting to the underlying standard contact elements may be laterally flanked by the respective metal components 441, thereby providing a highly complex metal structure in the layer 445, as already discussed above.

As also explained above, in some illustrative embodiments, at least some metal components 441C may be provided in combination with the modified contact elements 436, 336 (see FIG. 3A) in order to provide an additional direct connection to the metallization system 440, thereby ensuring low resistivity between respective source regions and the back gate region, while still reducing overall complexity in the metallization layer 445 and also providing reduced lateral distances, as is evident from FIG. 4A. In other cases, the respective metal components 442 of FIG. 4B may be implemented in some of the regions 443 in FIG. 4A, for instance, in combination with standard connect elements, such as 335 (see FIG. 3B) or in combination with modified contact elements 336 extending from the source region to the back gate region (see FIG. 3A). In any case, in any such embodiments, a low ohmic connection between respective source regions, back gate regions and the reference potential may also be accomplished.

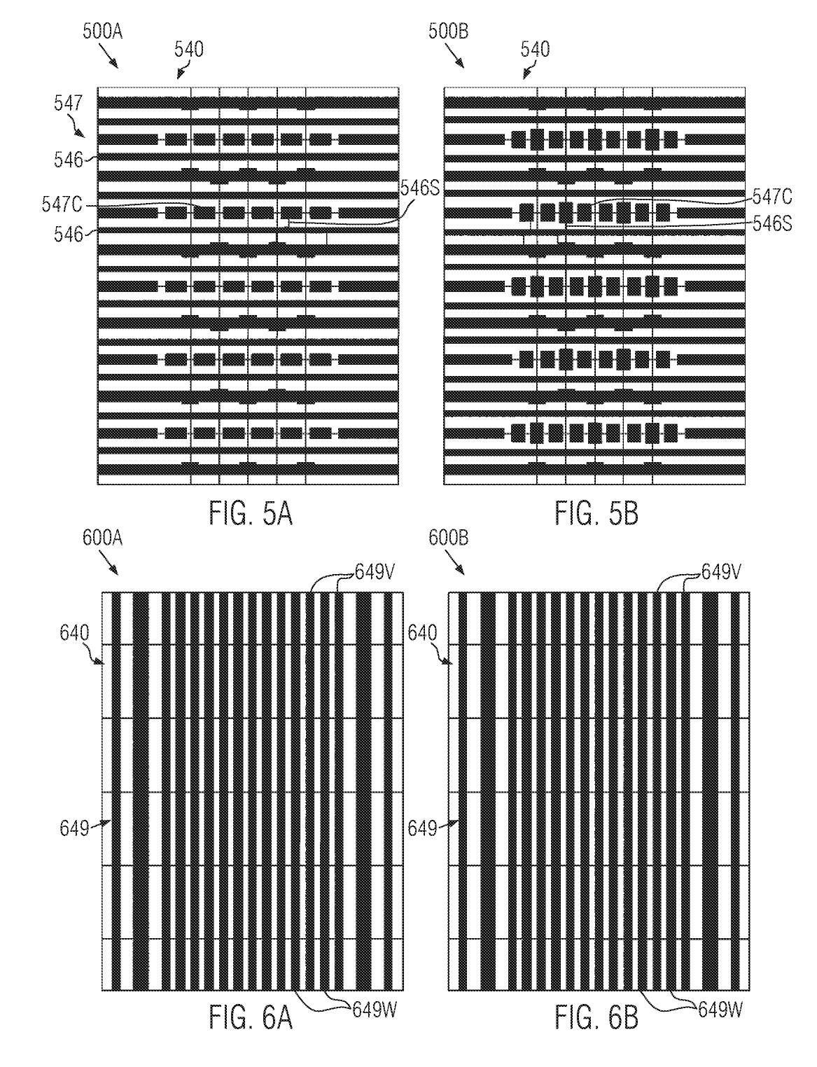

FIGS. 5A and 5B schematically illustrate devices 500A (FIG. 5A) and 500B (FIG. 5B) or their respective layouts, corresponding to the devices 400A, 400B in FIGS. 4A, 4B, in a subsequent metallization layer 547 of the metallization system 540. As illustrated in FIG. 5A, respective bit lines 546 may be provided for respective RAM cells in the horizontal direction, wherein, at areas in which the modified contact regime on the basis of contact elements, such as the elements 336 (see FIG. 3A), may be provided, the respective metal components 547C in the layer 547 connecting to the underlying metal layer may be rearranged or modified compared to corresponding metal component 547C, which may be provided in combination with the standard contact regime, for instance, as shown in FIGS. 3B and 4B, thereby obtaining a minimal lateral spacing 546S for the device 500A of, for instance, approximately 70 nm for a specific design under consideration, while the same minimal lateral spacing 546S in the device 500B may be significantly less, such as approximately 50 nm or even less. Consequently, in the metallization layer 547, having included therein the bit lines 546, the minimum lateral spacing between respective metal components 547C and bit lines 546 may be significantly increased, at least at areas in which the direct contact regime on the basis of omitted direct connections to the metallization system 540 are provided or, when respective direct connections to the metallization system 540 may be provided, the respective dimensions thereof may be reduced as, for instance, discussed in the context of FIG. 1B when referring to the central component 141, which may be provided with similar lateral dimensions as metal components directly connecting to standard contact elements 135 (see FIG. 1B). Consequently, by establishing the contact regime as discussed above, at least in some portions of the semiconductor device 500A, the total parasitic capacitance of the bit lines 546 may be reduced, and the process margins with respect to critical dimensions in the metallization layer 547 may also be increased.

FIGS. 6A and 6B schematically illustrate semiconductor devices or their layouts 600A (FIG. 6A) and 600B (FIG. 6B), similar to the configuration shown in FIGS. 5A, 5B, in top view with a further metallization layer 649 of a metallization system 640. In this layer, respective Word lines 649W may be provided in combination with supply voltage lines, in particular, with supply lines 649V carrying the reference potential or ground potential VSS. As is evident, in this metallization layer 649, both devices 600A and 600B have the same layout, thereby requiring no design changes when implementing the metallization layers 649. As illustrated, each Word line 649W may be laterally enclosed by the respective lines 649V, thereby achieving reduced cross-talking between neighboring Word lines 649W.

Consequently, when modifying the contact level so as to provide a contact element for directly connecting a respective source region with a back gate region, for instance, as discussed above in the context of FIGS. 2A-2C, respective modifications in layout may be achieved in the first metallization layer 445 (see FIGS. 4A, 4B) and in the subsequent metallization layer 547 (see FIGS. 5A, 5B), while the subsequent metallization layers may require no modifications. Therefore, superior process margin and/or performance may be accomplished on the basis of a given layout of certain device regions, such as densely packed RAM areas, substantially without requiring any modifications of manufacturing techniques, since, as discussed above, well-established process strategies may still be efficiently applied, while the contact level and the associated metallization layers may be formed on the basis of a modified layout or design. In some illustrative embodiments, as will be discussed in more detail with reference to FIG. 7, the overall floor space for at least some RAM cells or functional units may be reduced by providing the possibility of omitting dedicated connection mechanisms that may be conventionally required for connecting a desired reference potential, such as ground potential, to the doped semiconductor regions or back gate regions of transistor elements, such as transistors of a RAM cell.

FIG. 7 schematically illustrates a cross-sectional view of a semiconductor device 700, wherein basically the cross-section may be taken along a line similar to lines IB, IIB, as shown in FIGS. 1A and 2A. The semiconductor device 700 may, thus, include a substrate 701, a doped region 702 and a doped semiconductor region or back gate region 703, wherein respective isolation regions 704 may extend into the semiconductor region 703 and may laterally delineate respective active regions 705 of transistor elements, such as a transistor 750A. Furthermore, a connection mechanism 780 may be formed in the semiconductor device 700, wherein the mechanism 780 may establish a connection to a metallization system (not shown) so as to electrically connect the doped semiconductor region 703 with a desired reference potential, such as ground potential. To this end, the mechanism 780 may include a respective contact element 735 formed in a contact level 730, which may include dielectric materials 731, 732. Similarly, the transistor element 750A may be connected to a contact element 735 connecting to a source region 751, which may be provided in the form of a raised semiconductor region, as also discussed above. The source region 751 may include a highly conductive material 752, such as a metal silicide and the like, as also previously discussed.

It should be appreciated that components similar or analogous to the components of the previously described semiconductor devices 100B, 200A, 300A, 300B, 400A, 400B, 500A, 500B, 600A and 600B may be denoted by the same reference signs, except for the first digit, which may be a “7” for the semiconductor device 700. Consequently, any detailed description of these components and/or of any strategies for forming the same may be omitted, since the same criteria may apply as previously discussed in the context of the semiconductor devices described in the context of the previous figures.

The mechanism 780 may include a highly doped semiconductor material 781, possibly in combination with the highly conductive metal-containing material 752, wherein the material 781 may connect directly to a portion of the semiconductor region 703, thereby establishing an electrical connection. Thus, by providing the mechanism 780 for at least one of a plurality of transistor elements having the shared doped semiconductor region or back gate region 703, an efficient connection to the desired reference potential, such as ground potential, may be established.

As previously discussed, in some illustrative embodiments, the standard contact element 735 for connecting to the source region 751 may be replaced by a modified contact element 736 having an adapted lateral position and/or size, as previously discussed, in order to directly connect the source region 751 to the semiconductor region 703, as indicated by the dashed line. In this case, the mechanism 780 may efficiently connect the source region 751 with a corresponding reference potential via the region 781 and the contact element 735, wherein, as also discussed above, the current-carrying capacity of the mechanism 780 may be sufficient so as to supply current for even a relatively large number of respective transistor elements 750A, for instance, when provided in a plurality of RAM cells, as discussed above.

In further illustrative embodiments, as also explained in the context of the semiconductor devices 100B, 200A, some of the transistor elements 750A may be formed on the basis of the standard contact element 735, in combination with a direct connection to an overlying metallization system, thereby relaxing the demands for the current-carrying capacity of the mechanism 780, which may have to supply other transistor elements 750A having the modified contact element 736, however, without any direct connection to the overlying metallization system.

In still other illustrative embodiments, at least some of the transistor elements 750A may be provided with the modified contact element 736, wherein at least some of these contact elements 736 may have a direct connection to the metallization system, as for instance discussed in the context of FIG. 2B and, thus, to a respective supply line providing the required reference potential, such as ground potential. Consequently, also in this case, the modified contact element 736, in combination with the respective direct connection to the metallization system, may provide superior conductivity, since respective source regions 751 and related portions of the doped semiconductor material 703 may be connected to a low resistance path, thereby also relaxing the burden on the mechanism 780, which, in combination with the direct connection of modified contact elements 736 to the metallization system, may have to supply other transistor elements 750A having implemented the modified contact element 736 without a direct connection to the overlying metallization system, as also discussed above.

In still other illustrative embodiments, some of the transistor elements 750A may include a modified contact element 736, at least some of which may be directly connected to the metallization system, thereby establishing a low resistance path to the desired reference potential, such as ground potential, as discussed before. Due to this low resistance path, other transistor elements 750A having the modified contact element 736, however, without a direct connection to the overlying metallization system, may still be reliably connected to the reference potential at the source side and the respective portion of the semiconductor region 703, thereby providing the possibility of completely omitting the mechanism 780. Consequently, in some illustrative embodiments, the mechanism 780 may be omitted and the connection of the semiconductor region 703 to the reference potential may be established by at least one modified contact element 736, which may also be connected to the metallization system, for instance, as previously shown in the context of FIG. 2B. Consequently, a reduced overall floor space may suffice for forming the plurality of transistor elements 750A or the plurality of RAM cells, since none of these cells may have to include the mechanism 780.

It should be appreciated that the semiconductor device 700 as shown in FIG. 7 may be formed on the basis of manufacturing techniques as also previously discussed in the context of the semiconductor devices 100B, 200A, 300A, 300B, 400A, 400B, 500A, 500B, 600A and 600B.

As a result, the present disclosure provides semiconductor devices and manufacturing techniques in which at least some transistor elements formed on the basis of an FDSOI (fully depleted SOI) architecture may receive a contact element that provides a direct connection from the source region to the back gate region, which may result in superior design and manufacturing conditions for forming a respective metallization system. In particular, in RAM cells, the direct connection of source regions of pull-down transistors to the back gate region may provide reduced bit line capacitance, superior design of metallization layers and, thus, increased performance. That is, at least in some transistor elements, a direct connection of the source contact element to the metallization system may be omitted. In other cases, at least some transistor elements may still be connected to the metallization system, thereby increasing the current-carrying capacity of the back gate regions, while, in still other embodiments, a respective connection mechanism or regime for connecting the reference potential to the back gate region may be omitted, thereby reducing overall floor space of functional units in RAM areas.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A semiconductor device, comprising:
an active region of a transistor element, said transistor element comprising a source region;
an isolation structure laterally bordering said active region;
a buried insulating layer formed below said active region;
a doped semiconductor region formed below said buried insulating layer and electrically connected to a reference potential; and
a contact element formed in a dielectric material positioned adjacent said transistor element, said contact element connecting to said source region and extending to said doped semiconductor region so as to establish electrical connection to said reference potential.

2. The semiconductor device of claim 1, wherein said transistor element is part of a static random access memory (RAM) cell.

3. The semiconductor device of claim 2, wherein said contact element is formed and positioned so as to connect to a source region of a neighboring transistor element of a neighboring static RAM cell and laterally straddle an intermediate isolation region.

4. The semiconductor device of claim 1, wherein said transistor element comprises a channel region and said channel region includes a fully depleted channel portion.

5. The semiconductor device of claim 2, wherein said transistor element is a pull-down transistor of said static RAM cell.

6. The semiconductor device of claim 1, wherein said contact element is physically isolated from a metallization system of said semiconductor device by said dielectric material.

7. The semiconductor device of claim 2, further comprising a plurality of further static RAM cells, wherein said transistor element is physically isolated from a metallization system of said semiconductor device by said dielectric material, while at least one of said further static RAM cells comprises a further transistor element with a further contact element connecting to a source region of said further transistor element and directly connecting to said metallization system.

8. The semiconductor device of claim 7, wherein said further contact element connects to a further doped semiconductor region formed below said further transistor element.

9. The semiconductor device of claim 8, wherein said further doped semiconductor region is connected to said reference potential via said further contact element and said direct connection to said metallization system.

10. The semiconductor device of claim 9, wherein said doped semiconductor region and said further doped semiconductor region are directly connected to each other.

11. The semiconductor device of claim 7, wherein said static RAM cell and said plurality of further static RAM cells form a functional unit connected to a single word line and wherein electrical connection of said functional unit to said doped semiconductor region is exclusively established by one or more transistors having a contact element connecting to a respective source region and extending to said doped semiconductor region.

12. A semiconductor device, comprising:
a doped semiconductor region formed below a buried insulating layer, said doped semiconductor region being connected to a reference potential;
a plurality of RAM cells formed above said buried insulating layer and said doped semiconductor region; and
pull-down transistor elements provided in each of said plurality of RAM cells, at least one of said pull-down transistor elements comprising a source region that is connected to said doped semiconductor region by a contact element extending to said doped semiconductor region.

13. The semiconductor device of claim 12, wherein said contact element is physically isolated from a metallization system of said semiconductor device by a dielectric material enclosing said pull-down transistor elements.

14. The semiconductor device of claim 12, wherein said pull-down transistor elements comprise a fully depleted portion in a channel region thereof.

15. The semiconductor device of claim 12, wherein said contact element bridges said source regions of said pull-down transistor elements of two neighboring RAM cells.

16. The semiconductor device of claim 12, wherein at least one further pull-down transistor comprises a further source region that is connected to said metallization system by a further contact element that is directly connected to said metallization system.

17. The semiconductor device of claim 16, wherein said further contact element extends to said doped semiconductor region.

18. The semiconductor device of claim 12, wherein said plurality of static RAM cells form a functional unit connected to a single word line and wherein each static RAM cell of said functional unit lacks a semiconductor comprising connection region extending to said doped semiconductor region.

19. A method, comprising:
selecting at least one of lateral position and lateral shape of a contact element for a source region of a transistor element so as to provide lateral overlap of said contact element and an isolation region adjacent to said source region; and
forming said contact element on the basis of said lateral overlap so as to extend through a buried insulating layer and to a doped semiconductor region formed below said buried insulating layer and connectable to a reference potential.

20. The method of claim 19, further comprising forming a metallization system that is physically isolated from said contact element.
